(19) United States
(12) Patent Application Publication
(10) Pub. No.: US 2025/0301740 A1
(43) Pub. Date: Sep. 25, 2025

(54) SEMICONDUCTOR STRUCTURE AND METHOD OF FORMING THE SAME

(71) Applicant: HON HAI PRECISION INDUSTRY CO., LTD., New Taipei City (TW)

(72) Inventors: Jheng-Sheng YOU, New Taipei City (TW); Han-Chin CHIU, New Taipei City (TW); Wen-Yuan HSIEH, New Taipei City (TW)

(21) Appl. No.: 18/646,800

(22) Filed: Apr. 26, 2024

(30) Foreign Application Priority Data
Mar. 19, 2024 (TW) 113110190

(51) Int. Cl. H01L 29/20; H01L 21/311; H01L 21/3213; H01L 23/29; H01L 23/31; H01L 23/522; H01L 23/528

(52) U.S. Cl. CPC H10D 62/8503; H01L 21/31116; H01L 21/32136; H01L 23/291; H01L 23/3171; H01L 23/5226; H01L 23/5283

(57) ABSTRACT

The disclosure provides a semiconductor structure. The semiconductor structure includes a substrate, a gallium nitride layer, a dielectric layer, a passivation oxide layer, and a through gallium nitride via. The gallium nitride layer is on the substrate. The dielectric layer is on the gallium nitride layer. The passivation oxide layer is on the dielectric layer. The through gallium nitride via penetrates the gallium nitride layer and the dielectric layer, in which the through gallium nitride via has a flat surface, the flat surface extends from a surface where the through gallium nitride via is in contact with the gallium nitride layer to a surface where the through gallium nitride via is in contact with the dielectric layer, and the passivation oxide layer surrounds an upper portion of the through gallium nitride via.

### CROSS-REFERENCE TO RELATED APPLICATION

The application claims priority to Taiwan Application Serial Number 113110190, filed Mar. 19, 2024, incorporated herein in its entirety.

### BACKGROUND

### Field of Invention

The disclosure relates to a semiconductor structure and methods of forming the same.

### Description of Related Art

Gallium nitride (GaN) is widely used in power semiconductor components. Through gallium nitride via (through GaN via, TGV) is used as an electrical connection to dissipate the accumulated charge in the power semiconductor components. TGV can also include insulating dielectric materials to isolate the areas on the two sides of the TGV. However, GaN is difficult to be etched, and as the thickness of the GaN increases, it is more difficult to form the TGV. Moreover, the methods of forming the TGV are cumbersome. For example, a thick photoresist is required to form a TGV having a sufficient depth, and the photoresist is used multiple times to do the etching of forming the TGV. In addition, the quality of the TGV formed by existing methods is not as good as expected. For example, the photoresist residue remains in the TGV and the etching pattern is not straight enough. Therefore, it is necessary to develop a new semiconductor structure and a method of forming the same to efficiently form the TGV with good quality.

### SUMMARY

The disclosure provides a semiconductor structure including a GaN layer on a substrate, a dielectric layer on the GaN layer, a passivation oxide layer on the dielectric layer, and a through GaN via penetrating the GaN layer and the dielectric layer. The through GaN via has a flat side surface, the flat side surface extends from a surface of the through GaN via in contact with the GaN layer to a surface of the through GaN via in contact with the dielectric layer, and the passivation oxide layer surrounds an upper portion of the through GaN via.

The disclosure provides a method of forming a semiconductor structure, including the following operations. A semiconductor stack including a substrate, a GaN layer, and a dielectric layer arranged sequentially from bottom to top is received. A passivation oxide layer is formed on the dielectric layer. A photoresist layer having a first opening exposing the passivation oxide layer is formed on the passivation oxide layer. The passivation oxide layer and the dielectric layer underneath the first opening are etched to form a second opening in the passivation oxide layer and the dielectric layer. The GaN layer underneath the second opening is etched to form a third opening penetrating the GaN layer. The third opening is filled with a conductive material or an insulating dielectric material to form a through GaN via.

The disclosure provides a method of forming a semiconductor structure, including the following operations. A substrate, a GaN layer, a dielectric layer, and a passivation oxide layer are sequentially formed from bottom to top. The passivation oxide layer is patterned to form a first opening exposing the dielectric layer in the passivation oxide layer. The dielectric layer underneath the first opening is etched to form a second opening in the passivation oxide layer and the dielectric layer. The GaN layer underneath the second opening is etched to form a third opening penetrating the GaN layer. The third opening is filled with a conductive material or an insulating dielectric material to form a through GaN via. At least one portion of the passivation oxide layer is removed.

### BRIEF DESCRIPTION OF THE DRAWINGS

FIGS. 1A and 1B are cross-sectional views of the semiconductor structure according to some embodiments of the disclosure.

FIGS. 2 to 6 are cross-sectional views of the structures when forming the semiconductor structure according to some embodiments of the disclosure.

### DETAILED DESCRIPTION

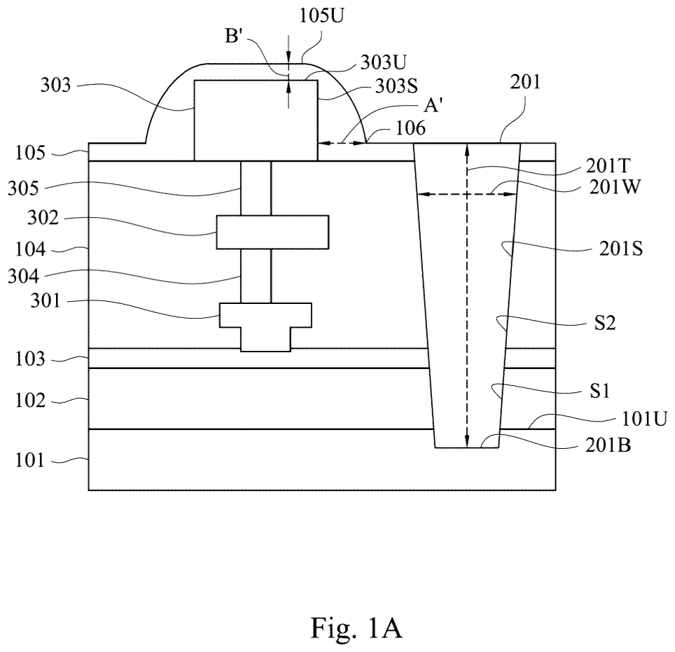

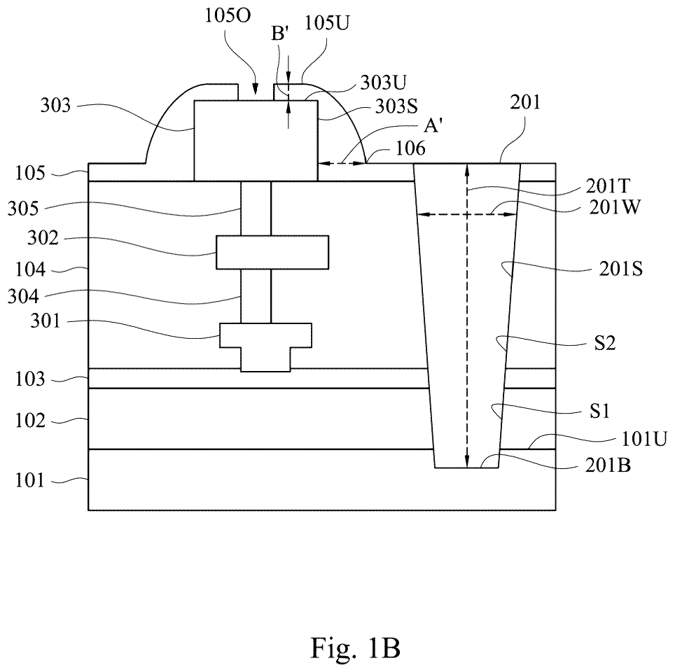

The disclosure provides a semiconductor structure shown in FIGS. 1A and 1B, including a GaN layer 102 on a substrate 101, a dielectric layer 104 on the GaN layer 102, a passivation oxide layer 105 on the dielectric layer 104, and a through GaN via 201 penetrating at least the GaN layer 102 and the dielectric layer 104. The through GaN via 201 has a flat side surface 201S extending from a surface S1 of the through GaN via 201 in contact with the GaN layer 102 to a surface S2 of the through GaN via 201 in contact with the dielectric layer 104. The passivation oxide layer 105 surrounds an upper portion of the through GaN via 201. Since the flat side surface 201S extends straight from the GaN layer 102 to the dielectric layer 104, the quality of the through GaN via 201 is good. For example, when the through GaN via 201 includes a conductive material, it can effectively dissipate the accumulated charge in the semiconductor structure, reduce the electrical resistance, and/or avoid the through GaN via 201 disconnected. When the through GaN via 201 includes an insulating dielectric material, it can effectively isolate the areas on two sides of the through GaN via 201.

In some embodiments, the flat side surface 201S extends continuously from an end of the through GaN via 201 away from the substrate 101 to an opposite end of the through GaN via 201 closer to the substrate 101, so the surfaces of the components in contact with the flat side surface 201S are substantially aligned with each other. In some embodiments, there is substantially no photoresist residue in the through GaN via 201. In some embodiments, a bottom surface 201B of the through GaN via 201 is lower than a top surface 101U of the substrate 101, so when the through GaN via 201 includes a conductive material, it is beneficial for the through GaN via 201 to dissipate the accumulated charge in the substrate 101. In some embodiments, a width 201W of the through GaN via 201 decreases from the end away from the substrate 101 to the opposite end closer to the substrate 101. In some embodiments, the cross-section of the through GaN via 201 is a trapezoid wider at the top and narrower at the bottom. In some embodiments, there is substantially no etching residue in the through GaN via 201. In some embodiments, the through GaN via 201 is next to a transistor (not drawn in whole in the figures). In some embodiments, the through GaN via 201 includes any suitable conductive material, e.g., metal, alloy, or a combination thereof, or an insulating dielectric layer to isolate different areas on two sides of the through GaN via 201.

In some embodiments, the substrate 101 may be any suitable semiconductor substrate and include any suitable semiconductor element, compound and/or alloy, e.g., carbon, silicon, germanium, silicon carbide, boron nitride, aluminum nitride, gallium nitride, gallium phosphide, gallium arsenide, indium phosphide, indium arsenide, indium antimonide, zinc oxide, SiGe, AlGaAs, InGaAs, InGaP, AlInAs, GaAsP, AIGaN, InGaN, AlGaInP, their analogues, or combinations thereof. In some embodiments, the substrate 101 includes an epitaxial seed layer (not drawn) to mitigate the lattice difference between the substrate 101 and the epitaxial material (e.g., the GaN layer 102 and/or an epitaxial buffer layer (not drawn)) on the substrate 101, and the seed layer can contact the through GaN via 201. In some embodiments, the seed layer includes silicon, silicon carbide, III-V compound, their analogues, or combinations thereof, and may be doped with N-type dopant or P-type dopant.

The GaN layer 102 provides the channel of the transistor. In some embodiments, the GaN layer 102 includes epitaxial gallium nitride. In some embodiments, the epitaxial buffer layer is between the substrate 101 and the GaN layer 102 to relieve the strain of the GaN layer 102. In some embodiments, the buffer layer includes epitaxial III-V compound, AlGaN, there analogues, or combinations thereof. In some embodiments, the through GaN via 201 penetrates the buffer layer. In some embodiments, the barrier layer 103 is on the GaN layer 102 to facilitate forming the channel having a high concentration of the two-dimensional electron gas in the GaN layer 102 to increase electron mobility and reduce resistance. In some embodiments, the barrier layer 103 includes AlGaN. In some embodiments, the through GaN via 201 penetrates the barrier layer 103.

The dielectric layer 104 is an interlayer dielectric to provide electrical insulation between the components. In some embodiments, the dielectric layer 104 may be one layer or multilayers, and each layer includes an electrical insulating material, e.g., silicon dioxide, silicon nitride, SiON, SiOCN, doped or undoped silicate glass, their analogues, or combinations thereof.

FIG. 1A schematically provides portions of the transistor (e.g., a high electron mobility transistor) including a source/drain electrode 301 and a vertical connection of the source/drain electrode 301. One skilled in the art knows that the transistor further includes remaining portions (e.g., a gate electrode, etc.) and a vertical connection thereof, which are not drawn specifically in the figures. Taking the source/drain electrode 301 and its vertical connection as an example, the source/drain electrode 301 in the dielectric layer 104 and on the GaN layer 102 defines a source/drain region in the GaN layer 102, and the vertical connection includes a conductive contact 302 in the dielectric layer 104 and a conductive layer 303 on the dielectric layer 104 to electrically connect the source/drain electrode 301. According to the requirements, the conductive contact 302 can electrically connect other components in the dielectric layer 104, and the conductive layer 303 can electrically connect other components outside the dielectric layer 104 to the source/drain electrode 301. In some embodiments, the source/drain electrode 301 connects the conductive contact 302 through a metal material 304, the conductive contact 302 connects the conductive layer 303 through a metal material 305, and the metal material 304 and the metal material 305 independently include W, Cu, or a combination thereof. In some embodiments, the source/drain electrode 301 includes any suitable metallic material that provides ohmic contact. In some embodiments, the conductive contact 302 and the conductive layer 303 independently include any suitable metallic material and may be the same or different from the material of the source/drain electrode 301.

In some embodiments, the passivation oxide layer 105 is on the dielectric layer 104, in which a projection of the passivation oxide layer 105 on the substrate 101 does not overlap with a projection of the through GaN via 201 on the substrate 101. The passivation oxide layer 105 is used as an etching mask to form the through GaN via 201. In some embodiments, the passivation oxide layer 105 surrounds the upper portion of the through GaN via 201. In some embodiments, an upper surface 105U of the passivation oxide layer 105 is curved and has rounded corners. In the embodiments including the conductive layer 303, the passivation oxide layer 105 covers a side surface 303S and an upper surface 303U of the conductive layer 303, in which the passivation oxide layer 105 has a thickest first thickness A′ and second thickness B′ respectively on the side surface 303S and the upper surface 303U. The thickness A′ is measured from a transition point 106 where the passivation oxide layer 105 changes from covering the conductive layer 303 to continuously covering the dielectric layer 104. The first thickness A′ is larger than the second thickness B′, and a ratio of the second thickness B′ to the first thickness A′ (i.e., B′/A′) is preferably from 0.7 to 0.9, e.g., 0.7, 0.75, 0.8, 0.85, or 0.9. In some embodiments, the passivation oxide layer 105 includes an insulating layer including passivation silicon dioxide, silicon nitride, SiON, Al₂O₃, or combinations thereof. In some embodiments, the through GaN via 201 penetrates the passivation oxide layer 105, and the flat side surface 201S contacts the passivation oxide layer 105. In some embodiments, the projection of the passivation oxide layer 105 on the substrate 101 is complementary to the projection of the through GaN via 201 on the substrate 101. In some embodiments, the passivation oxide layer 105 covers the whole upper surface 303U of the conductive layer 303, as shown in FIG. 1A, so the passivation oxide layer 105 can act as an encapsulation layer. Alternatively, the passivation oxide layer 105 has an opening 105O exposing at least a portion of the upper surface 303U of the conductive layer 303, as shown in FIG. 1B, so the conductive layer 303 can connect to other components through the opening 105O.

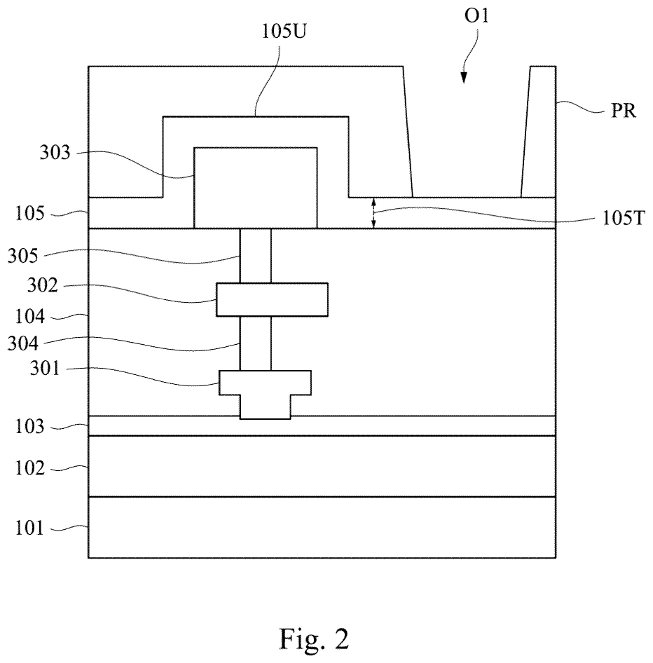

The disclosure also provides a method of forming the above-mentioned semiconductor structure. The method includes the following operations and can be referred to as having the structural changes shown in FIGS. 2 to 6. A semiconductor stack including the substrate 101, the GaN layer 102, and the dielectric layer 104 sequentially arranged from bottom to top is received, and the passivation oxide layer 105 is formed on the dielectric layer 104. Alternatively, the substrate 101, the GaN layer 102, the dielectric layer 104, and the passivation oxide layer 105 are formed sequentially from bottom to top. Then, the passivation oxide layer 105 is patterned to form an opening O2 in the passivation oxide layer 105 to expose the dielectric layer 104. The dielectric layer 104 underneath the opening O2 is etched to form an opening O3 in the passivation oxide layer 105 and the dielectric layer 104. In some embodiments, the passivation oxide layer 105 is etched by a photoresist layer PR having an opening O1 exposing the passivation oxide layer 105 on the passivation oxide layer 105 to form the opening 02, and the dielectric layer 104 underneath the opening O2 is successively etched to form the opening O3. The GaN layer 102 is etched by the opening O3 to form an opening O4 penetrating the GaN layer 102. The opening O4 is filled with a conductive material or an insulating dielectric material to form the through GaN via 201, as shown in FIGS. 1A and 1B. In some embodiments, at least a portion of the passivation oxide layer 105 is removed, as shown in FIG. 1B.

Refer to FIG. 2. In some embodiments, the semiconductor stack including the substrate 101, the GaN layer 102, and the dielectric layer 104 is received before performing a subsequent process. In some embodiments, the semiconductor stack further includes the seed layer, the buffer layer, the barrier layer 103, the transistor, the vertical connection of the transistor, or combinations thereof, as described above. The passivation oxide layer 105 is formed on the semiconductor stack, in which forming the passivation oxide layer 105 includes any suitable deposition process. In other embodiments, the substrate 101, the GaN layer 102, and the dielectric layer 104 are formed sequentially before forming the passivation oxide layer 105, in which forming the substrate 101, the GaN layer 102, the dielectric layer 104, and the passivation oxide layer 105 include any suitable deposition process. In some embodiments, forming the GaN layer 102 includes forming the GaN layer 102 on the substrate 101 including the seed layer described above. In some embodiments, before forming the GaN layer 102, the buffer layer described above is formed on the substrate 101. In some embodiments, after forming the GaN layer 102, the barrier layer 103 is formed on the GaN layer 102. In some embodiments, after forming the GaN layer 102 or the barrier layer 103, the transistor and the vertical connection described above are formed on the GaN layer 102 or the barrier layer 103. In some embodiments, forming the seed layer, the buffer layer, the barrier layers 103, the transistor, and the vertical connection include any suitable deposition process.

Continue referring to FIG. 2. The passivation oxide layer 105 is used as the etching mask to etch the GaN layer 102 in the subsequent process. In some embodiments, the passivation oxide layer 105 is conformally formed on the dielectric layer 104. In some embodiments, the passivation oxide layer 105 is conformally formed on the conductive layer 303.

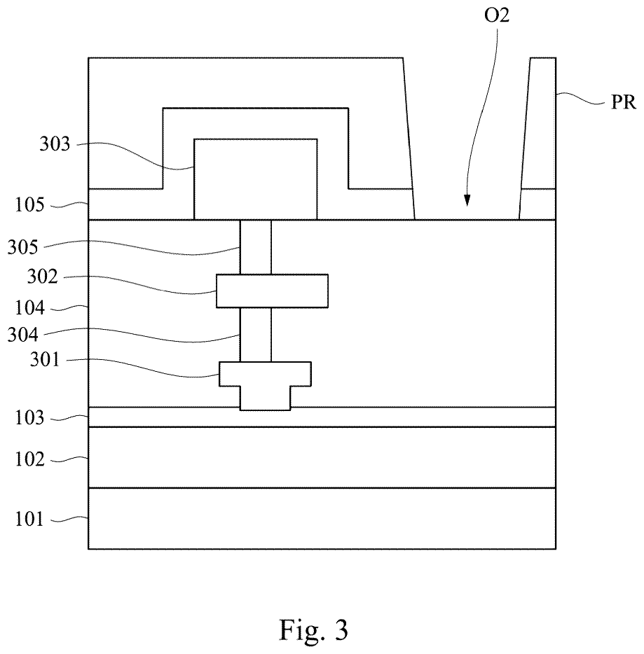

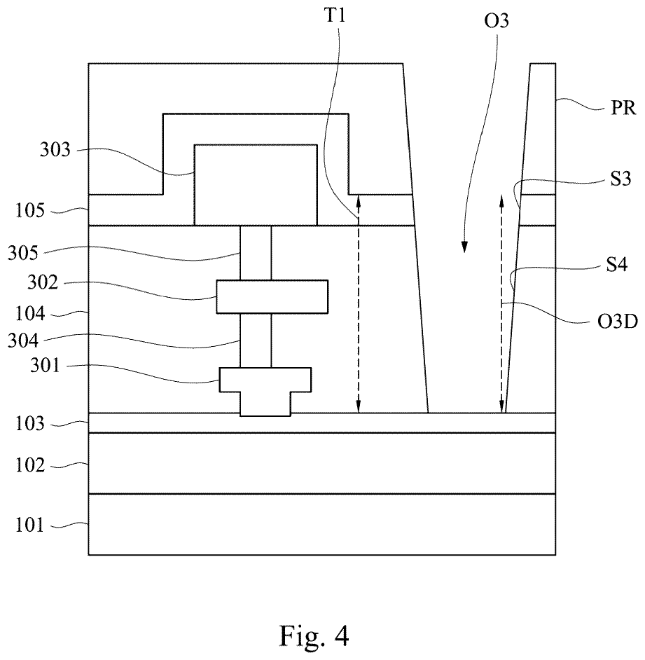

Continue referring to FIG. 2 and refer to FIGS. 3 to 4. The passivation oxide layer 105 is patterned by any suitable etching process to form the opening 02. The opening O2 defines the location where the through GaN via 201 will be formed. In some embodiments, patterning the passivation oxide layer 105 includes forming the photoresist layer PR having the opening O1 on the passivation oxide layer 105 to define the position where the through GaN via 201 will be formed by the opening O1, and transferring the pattern of the opening O1 to the passivation oxide layer 105 by any suitable etching process to form the opening O2. In some embodiments, the photoresist layer PR includes a positive photoresist or a negative photoresist, and the opening O1 is formed by a photolithography process.

Continue referring to FIG. 2 and refer to FIGS. 3 to 4. After forming the patterned passivation oxide layer 105 including the opening O2, any suitable etching process is performed to etch the dielectric layer 104 underneath the opening O2 to form the opening O3 penetrating the passivation oxide layer 105 and the dielectric layer 104, in which a flat side surface S3 of the passivation oxide layer 105 extends continuously to a flat side surface S4 of the dielectric layer 104 in the opening O3. In some embodiments, etching the passivation oxide layer 105 and the dielectric layer 104 is performed by a single and continuous etching process. In some embodiments, a total thickness T1 of the passivation oxide layer 105 and the dielectric layer 104 corresponds to a depth O3D of the opening O3. In the embodiments including the photoresist layer PR, a total etch rate to etch the passivation oxide layer 105 and the dielectric layer 104 is larger than an etch rate to etch the photoresist layer PR, for example, an etch selectivity of the passivation oxide layer 105 and the dielectric layer 104 to the photoresist layer PR (i.e., the total etch rate to etch the passivation oxide layer 105 and the dielectric layer 104 divided by the etch rate to etch the photoresist layer PR) is preferably from 1.5 to 2.5, e.g., 1.5, 2.0, or 2.5. In some embodiments, etching the passivation oxide layer 105 and the dielectric layer 104 substantially excludes etching the barrier layer 103, the GaN layer 102, and the components disposed below, so after forming the opening O3, the upper surface of the barrier layer 103 or the GaN layer 102 is exposed. In some embodiments, an additional and suitable process may be performed to remove the photoresist layer PR after forming the opening O3.

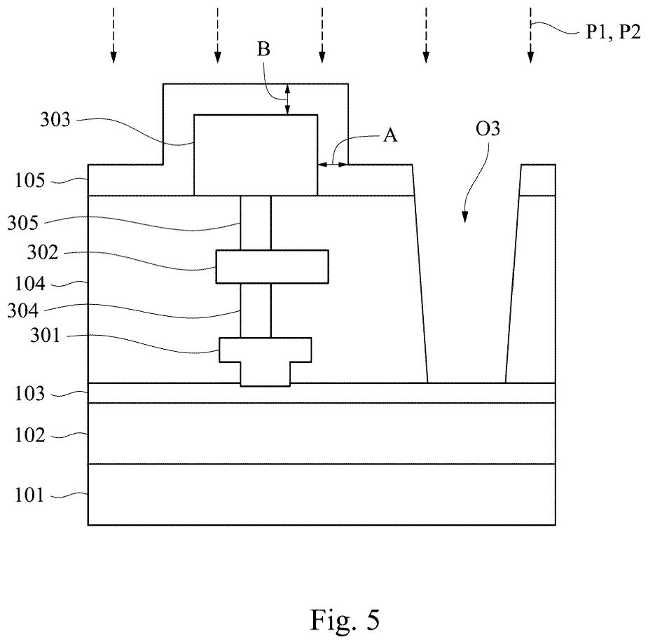

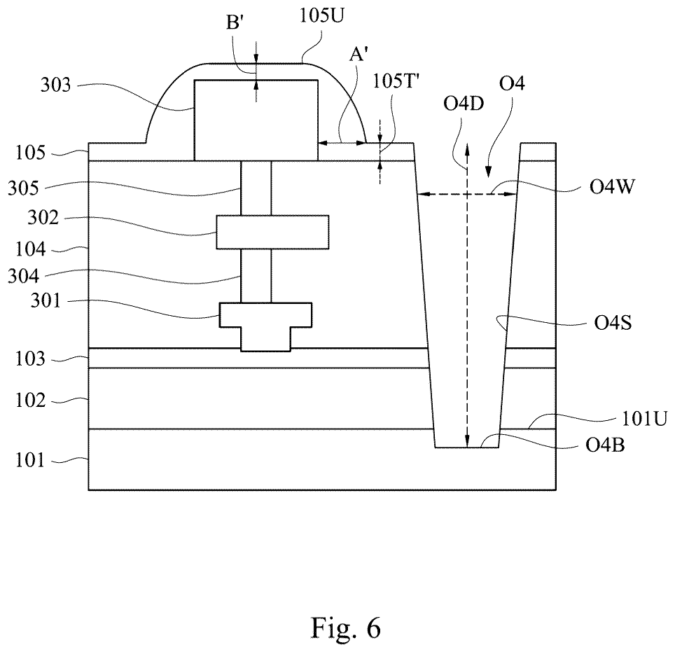

Refer to FIGS. 5 to 6. The GaN layer 102 is etched by the opening O3 to form the opening O4 penetrating the GaN layer 102. In some embodiments, if the photoresist layer PR remains on the passivation oxide layer 105, the remaining photoresist layer PR is removed when forming the opening O4. In the embodiments including the barrier layer 103, the method further includes etching the barrier layer 103 by the opening O3 to form the opening O4 penetrating the barrier layer 103. In the embodiments including the buffer layer, the method further includes etching the buffer layer by the opening O3 to form the opening O4 penetrating the buffer layer. In some embodiments, the method further includes etching a portion of the substrate 101 by the opening O3, so a bottom surface O4B of the opening O4 extends below the top surface 101U of the substrate 101. In some embodiments, the opening O4 extends to expose the seed layer of the substrate 101. In some embodiments, the opening O4 has a flat side surface O4S corresponding to the flat side surface 201S of the through GaN via 201 formed after filling a conductive material or an insulating dielectric material into the opening O4, in which the flat side surface O4S continuously extends from the top of the opening O4 to the bottom of the opening O4. In some embodiments, a depth O4D and a width O4W of the opening O4 are substantially equal to a thickness 201T and the width 201W of the through GaN via 201. After forming the opening O4, the passivation oxide layer 105 is exposed and may have a thickness 105T′ smaller than an original thickness 105T (see FIG. 2). In addition, owing to the anisotropic etching, the upper surface 105U of the passivation oxide layer 105 covering the side surface 303S and the upper surface 303U of the conductive layer 303 is curved and rounded, and the first thickness A′ and the second thickness B′ of the passivation oxide layer 105 on the side surface 303S and the upper surface 303U of the conductive layer 303 are smaller than an original first thickness A and an original second thickness B (see FIG. 5), in which the original first thickness A and the original second thickness B are substantially equal. In some embodiments, an etch amount on the original first thickness A is smaller than an etch amount on the original second thickness B (i.e., A′/B′>A/B).

Continue referring to FIGS. 5 to 6. In some embodiments, forming the opening O4 is performed by a single and continuous etching process, in which the etching process includes using an etching plasma, e.g., a chlorine plasma P1 and an argon plasma P2. In some embodiments, the opening O4 formed by the etching process has a low surface roughness. In some embodiments, the opening O4 formed by the etching process substantially excludes an etching residue. In some embodiments, since the etching process excludes using an additional photoresist, the opening O4 formed substantially excludes a photoresist residue. In some embodiments, an etch rate to etch the GaN layer 102 is larger than an etch rate to etch the passivation oxide layer 105, for example, an etch selectivity of the GaN layer 102 to the passivation oxide layer 105 (i.e., the etch rate to etch the GaN layer 102 divided by the etch rate to etch the passivation oxide layer 105) is preferably from 22 to 36, e.g., 22, 24, 26, 28, 30, 32, 34, or 36. For example, the etch rate to etch the GaN layer 102 is about 190 nm/min to about 280 nm/min, and the etch rate to etch the passivation oxide layer 105 is from about 7.8 nm/min to about 8.5 nm/min. In some embodiments, the process pressure in the etching process is preferably from 1.5 mTorr to 5.0 mTorr, e.g., 1.5 mTorr, 2.0 mTorr, 2.5 mTorr, 3.0 mTorr, 3.5 mTorr, 4.0 mTorr, 4.5 mTorr, or 5.0 mTorr.

Continue referring to FIGS. 5 to 6. In some embodiments, a flow rate ratio of the chlorine plasma P1 to the argon plasma P2 in the etching process is preferably from 1.0 to 2.4, e.g. 1.0, 1.2, 1.5, 1.7, 2.0, 2.2, or 2.4, in which a flow rate of the chlorine plasma P1 is preferably from 25 sccm to 35 sccm (e.g., 25 sccm, 30 sccm or 35 sccm), and a flow rate of the argon plasma P2 is preferably from 15 sccm to 25 sccm (e.g., 15 sccm, 20 sccm, or 25 sccm). When the flow rate ratio is in the above range, an amount of the chlorine plasma P1 having the etch reactivity and an amount of the argon plasma P2 providing the physical sputtering are sufficient to form a deep enough opening O4, and the quality of the pattern of the opening O4 is good. For example, when the flow rate ratio is in the above range, excessively etching the passivation oxide layer 105 that is used as the etching mask by too much argon plasma P2 is avoided, thereby preventing the pattern of the opening O4 from not forming as expected, too much argon plasma P2 is prevented from causing the roughness of the surface in the opening O4 to increase, and too much chlorine plasma P1 is prevented from causing the surface in the opening O4 to have an etching defect (i.e., etch pits). In some embodiments, when the flow rate ratio is in the above range, the etch rate to etch the GaN layer 102 increases as the flow rate ratio increases because the chlorine plasma P1 having a larger etch reactivity to the GaN layer 102 is increased, and the etch rate to etch the passivation oxide layer 105 decreases as the flow rate ratio increases because the argon plasma P2 providing the physical sputtering to the passivation oxide layer 105 is decreased. Therefore, the etch selectivity of the GaN layer 102 to the passivation oxide layer 105 increases as the flow rate ratio increases.

Continue referring to FIGS. 5 to 6. In some embodiments, a radio frequency (RF) power to form the etching plasma in the etching process is preferably from 80 W to 100 W, e.g., 80 W, 85 W, 90 W, 95 W, or 100 W. When the RF power is in the above range, the physical sputtering by the plasma is sufficient to perform an ion bombardment to reach a desired etch rate, thereby forming a deep enough opening O4 as expected. Specifically, when the RF power is in the above range, the etch rate reduction is avoided when the RF power is too high. When the RF power is too high, the etching reaction may have not yet occurred on the etching surface but the plasma has left the etching surface due to the sputtering. When the RF power is in the above range, the etching efficiency is avoided to decrease when too low RF power causes a lower etch rate. In addition, when the RF power is in the above range, the pattern quality of the opening O4 is improved. For example, when the RF power is in the above range, too high RF power is avoided to cause the passivation oxide layer 105 that acts as the etching mask to be over-etched, thereby preventing the opening O4 from having an unexpected pattern, too high RF power is avoided to cause the roughness of the etching surface to increase, too low RF power is avoided to increase the isotropic etching that may cause an etching undercut, a sufficient anisotropic etching is guaranteed to make the pattern of the opening O4 straighter, and the etching by-product is more easily desorbed from the semiconductor structure by the physical sputtering of the etching plasma. In some embodiments, when the RF power is in the above range, the etch rate to etch the GaN layer 102 and the passivation oxide layer 105 increases as the RF power increases, in which the increment of the etch rate to etch the passivation oxide layer 105 is larger than the increment of the etch rate to etch the GaN layer 102, so the etch selectivity of the GaN layer 102 to the passivation oxide layer 105 decreases as the RF power increases.

Refer to FIGS. 1A, 1B, and 6. A conductive material or an insulating dielectric material is filled into the opening O4 to form the through GaN via 201 shown in FIGS. 1A and 1B. In some implementations, the conductive material or the insulating dielectric material is filled by any suitable deposition process. In some embodiments, at least a portion of the passivation oxide layer 105 is removed to form the opening 105O to make at least a portion of the conductive layer 303 exposed by the opening 105O, as shown in FIG. 1B. In some embodiments, removing the passivation oxide layer 105 includes any suitable etching process.

The semiconductor structure and the semiconductor structure formed by the method in the disclosure include improved through GaN via, for example, having a sufficient thickness, a straighter side surface, and no photoresist and etching residues. In addition, when the through GaN via include a conductive materials, the through GaN via can effectively dissipate the accumulated charge in the semiconductor structure to make the semiconductor structure suitable for acting as a high power semiconductor component. When the through GaN via includes an insulating dielectric materials, it can effectively isolate regions besides the through GaN via. In addition, the method is easy, and the two stages of the self-aligning etching is used to etch the opening O3 and the opening O4. Therefore, in addition to the sidewall of the opening O3 and the sidewall of the opening O4 extending continuously and flatly from the top of the opening to the bottom of the opening in the cross-sectional view, multiple steps of using the photoresist are avoided to avoid performing multiple exposure processes that increase the process cost.

What is claimed is:

1. A semiconductor structure, comprising:
a substrate;
a gallium nitride layer on the substrate;
a dielectric layer on the gallium nitride layer;
a passivation oxide layer on the dielectric layer; and
a through gallium nitride via penetrating the gallium nitride layer and the dielectric layer, wherein the through gallium nitride via has a flat side surface, the flat side surface extends from a surface of the through gallium nitride via in contact with the gallium nitride layer to a surface of the through gallium nitride via in contact with the dielectric layer, and the passivation oxide layer surrounds an upper portion of the through gallium nitride via.

2. The semiconductor structure of claim 1, wherein a bottom surface of the through gallium nitride via is located below a top surface of the substrate.

3. The semiconductor structure of claim 1, wherein an upper surface of the passivation oxide layer is curved.

4. The semiconductor structure of claim 1, further comprising a conductive layer disposed on the dielectric layer and covered by the passivation oxide layer, wherein the passivation oxide layer has a first thickness on a side surface of the conductive layer, the passivation oxide layer has a second thickness on an upper surface of the conductive layer, and the first thickness is larger than the second thickness.

5. A method of forming a semiconductor structure, comprising:
receiving a semiconductor stack, wherein the semiconductor stack comprises a substrate, a gallium nitride layer, and a dielectric layer arranged sequentially from bottom to top;
forming a passivation oxide layer on the dielectric layer;
forming a photoresist layer on the passivation oxide layer, wherein the photoresist layer has a first opening exposing the passivation oxide layer;
etching the passivation oxide layer and the dielectric layer underneath the first opening to form a second opening in the passivation oxide layer and the dielectric layer;
etching the gallium nitride layer underneath the second opening to form a third opening penetrating the gallium nitride layer; and
filling the third opening with a conductive material or an insulating dielectric material to form a through gallium nitride via.

6. The method of claim 5, wherein an etch selectivity of the gallium nitride layer to the passivation oxide layer is from 22 to 36.

7. The method of claim 5, wherein etching the gallium nitride layer underneath the second opening comprises using a chlorine plasma and an argon plasma.

8. A method of forming a semiconductor structure, comprising:
sequentially forming a substrate, a gallium nitride layer, a dielectric layer, and a passivation oxide layer from bottom to top;
patterning the passivation oxide layer to form a first opening in the passivation oxide layer, wherein the first opening exposes the dielectric layer;
etching the dielectric layer underneath the first opening to form a second opening in the passivation oxide layer and the dielectric layer;
etching the gallium nitride layer underneath the second opening to form a third opening penetrating the gallium nitride layer;
filling the third opening with a conductive material or an insulating dielectric material to form a through gallium nitride via; and
removing at least one portion of the passivation oxide layer.

9. The method of claim 8, further comprising forming a conductive layer disposed on the dielectric layer and covered by the passivation oxide layer, wherein after removing the at least one portion of the passivation oxide layer, at least one portion of the passivation oxide layer is exposed.

10. The method of claim 8, wherein a sidewall of the third opening extends continuously and flatly from a top portion of the third opening to a bottom portion of the third opening.
